(19) United States
(12) Patent Application Publication
(10) Pub. No.: US 2014/0353277 A1
(43) Pub. Date: Dec. 4, 2014

(54) METHOD FOR FABRICATING DEFECT FREE SILICON MOLD INSERT

(71) Applicants: GREENCORE TECHNOLOGY CO. LTD., Guishan Township (TW); NANOCRYSTAL (ASIA) INC., Taipei (TW)

(72) Inventors: Chong-Ming LEE, Taipei (TW); Chung-Hua LEE, Guishan Township (TW)

(73) Assignees: Greencore Technology Co. Ltd.; Nanocrystal (Asia) Inc.

(21) Appl. No.: 13/943,373

(22) Filed: Jul. 16, 2013

(30) Foreign Application Priority Data
May 31, 2013 (TW) 102119501

(51) Int. Cl. H01L 21/033

(52) U.S. Cl. CPC H01L 21/033
USPC 216/51

(57) ABSTRACT

The present invention discloses a method for fabricating a default free silicon mold insert. The method includes providing a silicon mold insert substrate, producing a photoresist pattern, coating a metal film, removing the photoresist pattern, performing heating and annealing, performing dry etching, and removing the metal balls so as to fabricate the default free silicon mold insert. The default free silicon mold insert produced by the method of the present invention can be applied to the nonoimprint process in manufacturing epitaxy wafers to microscopicly provide uniform distances of patterns on the silicon mold insert, and macroscopicly eliminate the grid lines on the epitaxy wafers, and enormously raise the throughput of epitaxy wafer productions. With the ease of application, cheap and fully reproducible nature of the default free silicon mold insert, nanoimprint technology can really replace the stepper machines used nowadays for producing default free nanoimprint mold insert.

### BACKGROUND OF THE INVENTION

1. Technical Field

The present invention is related to a method for fabricating defect free silicon mold insert, and more particularly to a method for fabricating defect free silicon mold insert used for the nono imprint process in manufacturing epitaxial wafers.

2. Description of Related Art

Patterned sapphire substrate (Patterned Sapphire Substrate, PSS) is generally having its patterns created by means of yellow light manufacturing process. Among all, stepper is the most popular process. However, the patterns created by the stepper have flaws or tolerances in the patterns serious to a degree that those flaws are visible to the naked eye. These flawed patterns are so called grid lines by the manufacturers of the sapphire substrate. On the other hand, the flawed patterns will inevitably result the defects of the sapphire substrate and scratches and grid lines are most common defects found on the substrate. If the scratches on the defected substrate are too severe, it will penetrate the epitaxial wafer. Accordingly, the loss resulted from the damaged area across the epitaxial wafer by the grid lines is much larger than the loss caused by the scratches.

Problems related to grid lines can be mainly categorized to grid dislocation, overlap or separation, and would cause serious epitaxial defects. Accordingly, it has become a key criterion of PSS epitaxial plant to determine whether a substrate has met the requirements or not. Normally, the epitaxial plant will use a very strong light beam toward the surface of the wafer and then to detect visually with naked eyes for whether there are grid lines across the surface of the PSS substrate. If the grid lines are illegible, then the wafer is passed. However, if the grid lines are clear to see, and the wafer will be further checked with microscope for further confirmation. If the grid lines are confirmed under the microscope, then the wafer will be categorized as failed. Grid lines are inevitable in the typical manufacturing processes of the PSS manufacturer. If the situation is too serious, then the PSS with the defected grid lines will cause a large defective area across the epitaxial wafer. Eventually, the failed wafer created by the grid lines will be much more than the failed wafer caused by other defects.

Referring to FIG. 1A, an illustrational view of grid lines of a conventional epitaxial wafer; FIG. 1B is a photo showing a conventional epitaxial wafer and grid lines; and FIG. 1C is an illustrational view showing scratches on a conventional epitaxial wafer. Based on the manufacturing techniques current available for the epitaxial wafer, one out of ten wafers can be found with the grid lines easily, i.e. the defective rate is 10%, and it can be said that the waste is quite severe.

Making the epitaxial wafer free of grid lines would be the vital and golden opportunity for the nano imprinting process to replace the stepper during the manufacturing process of the epitaxial wafer. In addition, in the nano imprinting lithography, the manufacturing of the mold insert is very important, and the good or bad of the mold insert play an vital role in the yield of the epitaxial as well as its manufacturing processes. In light of this, how to create and invent a repeatable manufacturing process featured simple, low cost, and effectively eliminating the grid lines on the mold lines, has become a key performance index for the developmental direction and targets. Not only for the technical field of nano imprinting lithography, patterned sapphire substrate, but also to the light emitted diode.

### SUMMARY OF THE INVENTION

The present invention relates a method for fabricating a defect free silicon mold insert, and includes the steps of providing a silicon mold insert substrate, producing a photoresist pattern, coating a metal film, removing the photoresist pattern, performing heating and annealing, performing dry etching, and removing the metal balls so as to fabricate the default free silicon mold insert. The defect free silicon mold insert produced by the method of the present invention can be utilized to the nono imprint lithography process in manufacturing epitaxial wafer to microscopically provide uniform distances of patterns on the silicon mold insert, and macroscopically eliminate the grid lines on the epitaxial wafers, and enormously raise the throughput of epitaxial wafer productions. With the ease of application, cheap and fully reproducible nature of the defect free silicon mold insert, nano imprint technology can really be used to replace the stepper machines used nowadays for producing defect free nano imprint mold insert.

The present invention relates to a method for fabricating defect-free silicon mold insert for Nano imprint lithography, comprising the steps of providing a mold insert; creating a photoresist pattern onto the mold insert, and further deploying a photoresist layer, exposing the photoresist layer with a mask and further performing developing process so as to create the photoresist pattern in which a plurality of holes are defined; depositing a metal film covering the photoresist pattern and the plurality of holes; creating a plurality of metal posts used to retrieve the metal film and the photoresist pattern, wherein the metal posts are created on the photoresist pattern in positions corresponding to the plurality of holes; conducting a heating and annealing process melting the metal posts into a plurality of metal sections with heat and each of the metal sections being in a position corresponding to the original metal post, wherein every two adjacent metal sections are separated from each other, and annealing the metal sections into a plurality of metal balls; conducting a dry etching process aiming to the mold insert having the metal balls so as to create a plurality of recesses on the mold insert through the gaps between the metal balls, defining a plurality of patterns by the recesses which is distant from each other with a yardstick of a radius of the metal ball; and removing the metal balls from the mold insert so as to create a defect-free silicon mold insert having patterns with uniformed distance from each other.

With the implementation of the present invention, the present invention can conclude with the following advantages.

1. Automatically modify the distance and offset error between the patterns of the mold insert.

2. Creating a uniform dimension of the pattern and ensuring equal distance between patterns.

3. Effectively eliminating grid lines of the mold insert so as to ensure a creation of a defect free silicon mold insert.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1A is an illustrational view of grid lines of a conventional epitaxial wafer;

FIG. 1B is a photo showing a conventional epitaxial wafer and grid lines;

FIG. 1C is an illustrational view showing scratches on a conventional epitaxial wafer;

FIG. 2 is a flow diagram for the steps of method for fabricating defect-free silicon mold insert for nano imprint lithography in a preferred embodiment made in accordance with the present invention;

FIG. 3 is a cross sectional view showing a mold insert is deployed with a photoresist layer in a preferred embodiment made in accordance with the present invention;

FIG. 4 is an illustrational view showing the photoresist layer on the mold insert is undergoing exposure in a preferred embodiment made in accordance with the present invention;

FIG. 5 is an illustrational view showing the formation of a photoresist pattern in a preferred embodiment made in accordance with the present invention;

FIG. 6 is a cross sectional view of a deposited metal film in a preferred embodiment made in accordance with the present invention

FIG. 7 is a cross sectional view of a metal post used for the removal of the metal film in a preferred embodiment made in accordance with the present invention;

FIG. 8 is an illustrational and cross sectional view showing a heating process to transform the metal post into a metal section in a preferred embodiment made in accordance with the present invention;

FIG. 9 is an illustrational and cross sectional view showing an annealing process to transform the metal section into a metal ball in a preferred embodiment made in accordance with the present invention;

FIG. 10 is an illustrational and cross sectional view showing a dry etching process to form a recess in a preferred embodiment made in accordance with the present invention;

FIG. 11 is an illustrational and cross sectional view showing a removal of the metal ball to create a defect-free silicon mold insert in a preferred embodiment made in accordance with the present invention; and

FIG. 12 is an illustrational view showing an epitaxial wafer free of any grid lines or scratches made in a preferred embodiment made in accordance with the present invention.

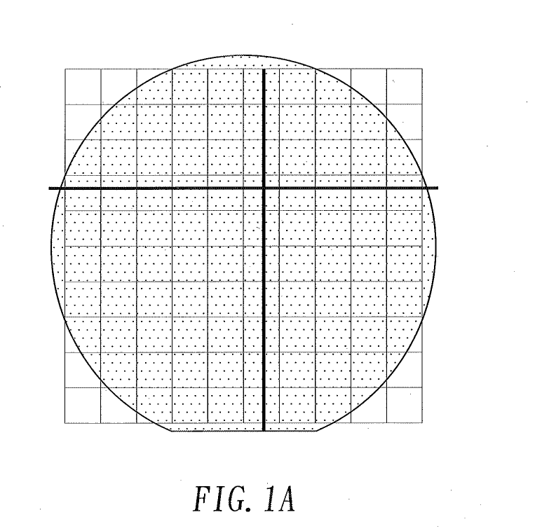

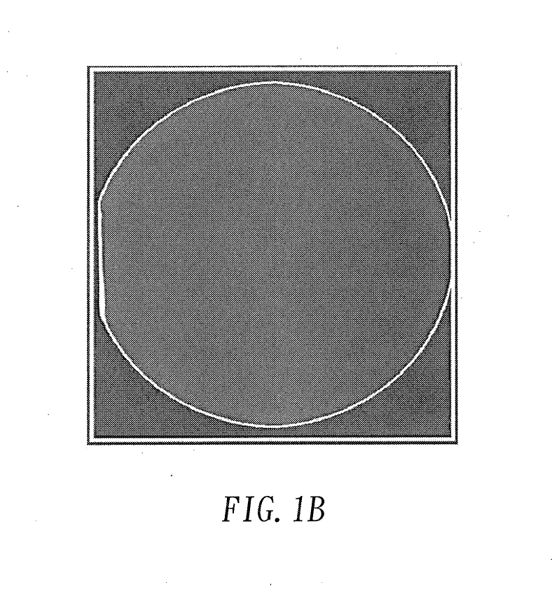

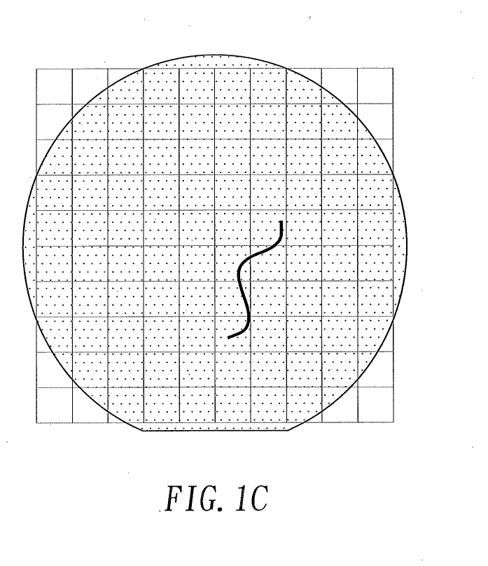

### DETAILED DESCRIPTION OF THE EMBODIMENTS OF THE INVENTION

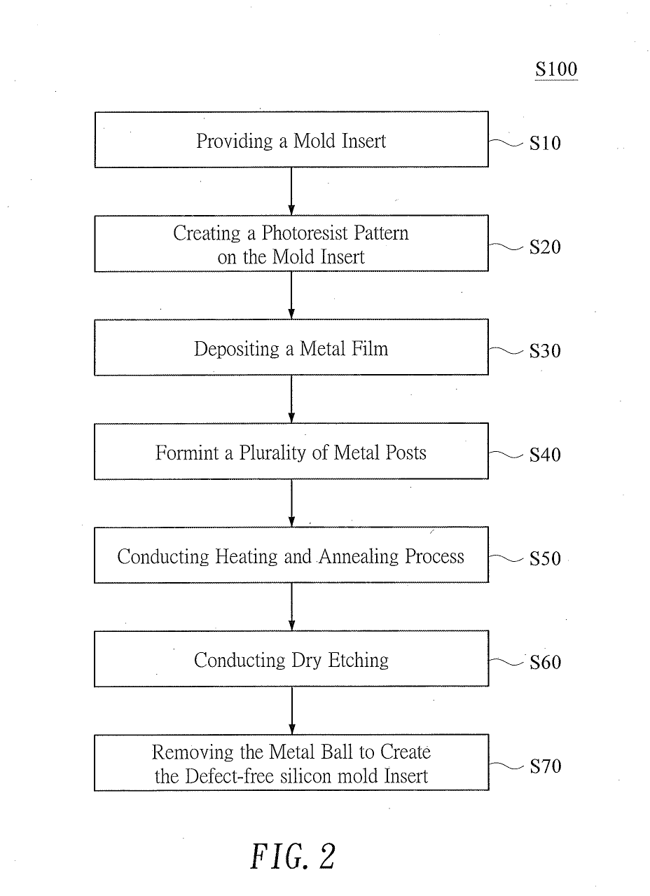

As shown in FIG. 2, a method for fabricating defect-free silicon mold insert (S100) includes the steps of providing a mold insert (step S10); creating a photoresist pattern (step S20); Depositing a metal film (step S30); forming a plurality of metal posts (step S40); conducting heating and annealing process (step S50); conducting dry etching (step S60); and removing the metal balls to create the defect-free silicon mold insert (step S70).

As shown in FIGS. 2 and 3, the step of providing a mold insert (step S10), and the mold insert 10 is used to serve as a substrate on which a pattern is further formed thereon. The mold insert is a hard substrate which is made from a monocrystalline silicon (s-Si), polycrystalline silicon (c-Si), silicon oxide (SiOx), silicon carbide (SiC), aluminum nitride (AlN), alumina (Al₂O₃), spinel (MgAl₂O₄), zinc selenide (ZnSe), zinc oxide (ZnO), gallium nitride (GaN), gallium phosphide (GaP), or a combination of more than two of the above-mentioned material.

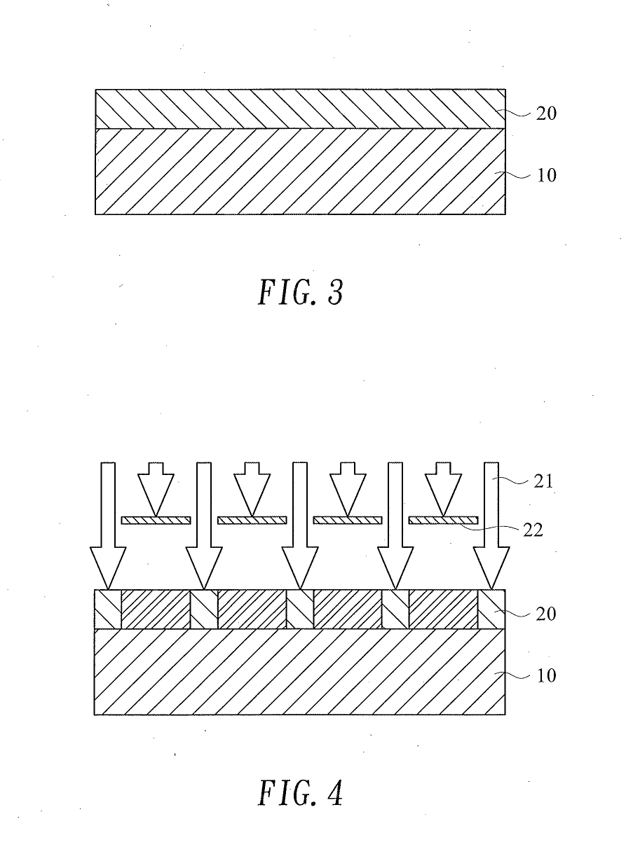

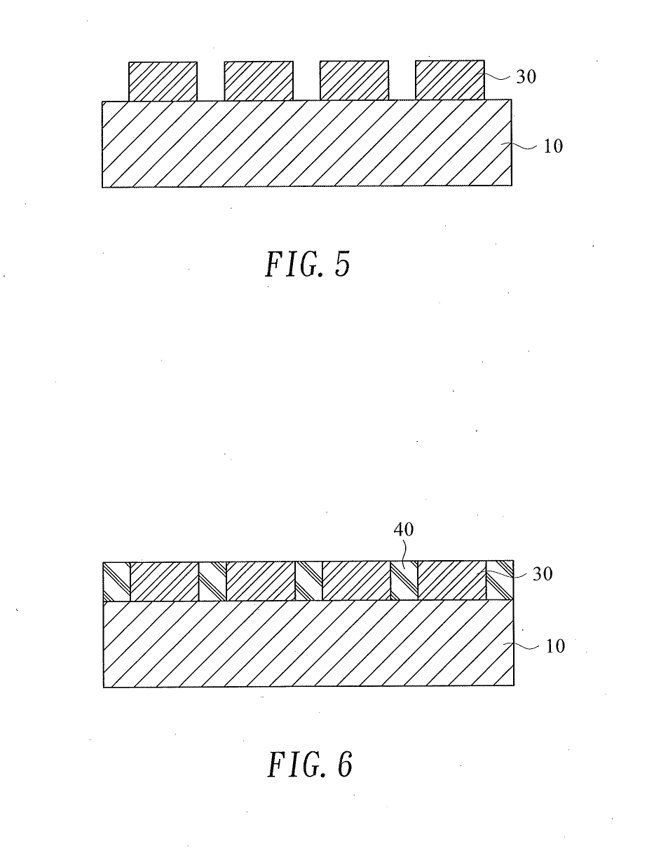

Referring to FIGS. 2, 4 and 5, a process of manufacturing a photoresist pattern over the mold insert dis disclosed, i.e. step S20. The mold insert 10 is coated with a photoresist layer 20, and then exposed under a light source 21 with a pre-selected wavelength after the photoresist layer 20 is covered with a mask 22. Afterward, the photoresist layer 20 is developed so as to create the photoresist pattern 30. During the exposure to the photoresist layer 20, and then developing, the material of the photoresist layer 20 can be readily changed in view of the light source 21, i.e. wavelength, used. For example, in case krypton monofluoride (KrF) is used, which has a wavelength of 248 nm, as the light source 21, then the photoresist layer 20 will be made from polyhydroxy styrene and derivatives. In case argon fluoride (ArF) is used as the light source 21, and it has a wavelength of 193 nm, then cycloaliphatic polyester acrylates and copolymers thereof will be used to make the photoresist layer 20. If the extreme ultraviolet is used as the light source 21, and it has a wavelength of 13.5 nm, then polyester derivatives and molecular glass single-component material will be used to make the photoresist layer 20.

Referring to FIGS. 2 and 6, the step of depositing a metal film (step S30) is to deposit a metal film 40 over the surface of the mold insert 10 which is not covered by the photoresist pattern 30. The metal film 40 used to deposit over the mold insert 10 can be scandium (Sc), titanium (Ti), vanadium (V), chromium (Cr), manganese (Mn), iron (Fe), cobalt (Co), nickel (Ni), copper (Cu), zinc (Zn), or a combination of more than any two of the metal described above.

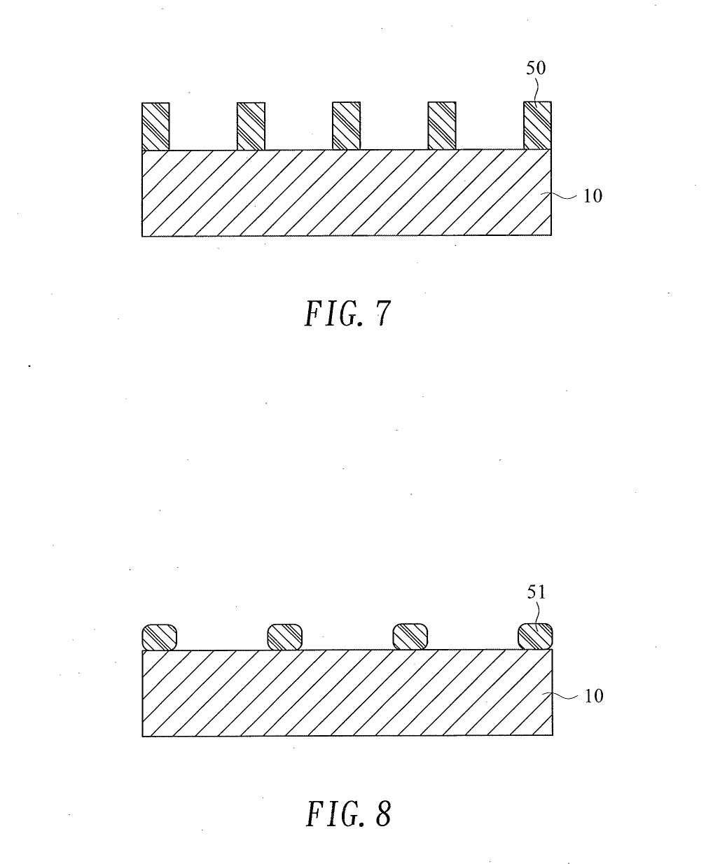

Referring to FIGS. 2 and 7, the step of creating a plurality of metal posts (step S40) is to pull off the photoresist pattern 30 and the metal film 40. As a result, the surface of the mold insert 10 uncovered with the photoresist pattern 30 is created with a plurality of metal posts 50 corresponding to the photoresist pattern 30.

As shown in FIGS. 2, 7 and 8, conducting a process of heating and annealing (step S50). Firstly, the metal posts 50 are heated such that each of the meal posts 50 is transformed into a corresponding metal section 51. Every two adjacent metal sections 51 are free from bridging. Accordingly, the metal sections 51 transformed from the metal posts 50 are separated from each other.

Referring to FIGS. 2, 8 and 9, after the metal sections 51 are created, a process of annealing is conducted such that the metal sections 51 are cooled down in a controlled manner to room temperature such that each of the metal sections 51 is transformed into a metal ball 52. The radius and roundness of each of the metal balls are identical to each other.

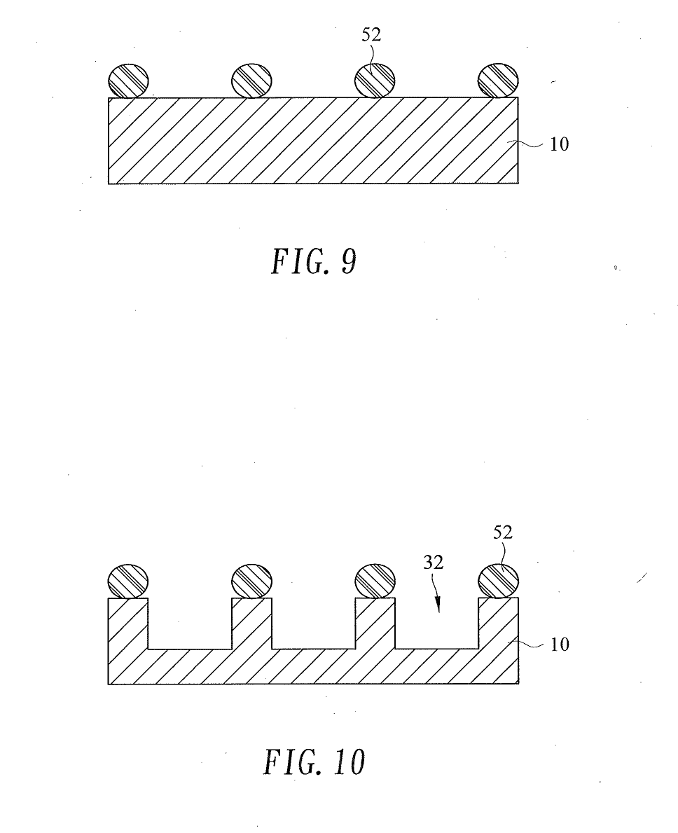

As shown in FIG. 9, the formation of the metal balls 52 is based on a principle that when a substance is transformed from liquid state into a solid state, the potential heat energy is gradually released such as during the anneal process. During this process, the external change of the substance follows strictly the principle of minimum surface energy. On the other hand, the surface energy is proportionally to the surface area. Accordingly, when the substance has the smallest surface area, it has the minimum surface energy. It is well known that within the same volume, a spherical area is the smallest area. As a result, a ball or sphere will have the smallest surface energy. In light of this, each of the metal sections 51 will be gradually transformed into a metal ball 52 after undergoing the annealing process.

Taking chrome (Cr) as an example, when the heating and annealing process (step S50) is conducted, the mold insert 10 along with the metal posts 50 is disposed within a quick annealing oven of high-vacuum or normal atmosphere pressure of noble gas. Once the mold insert 10 is disposed, the temperature is heated to 1850˜1905 degrees Celsius. The reason for heating up the oven to such temperature in such a short period of time is to reduce a so-called eutectic effect between the metal post 50 and the mold insert 10. Normally, the melting point of the alloy is lower then the melting point of metal. The high vacuum and noble gas is used to prevent any reaction between the metal and the molecule of the gas, such as oxygen (O2), nitrogen (N2), hydrogen (H2), and carbon dioxide (CO2). The final temperature of the quick heating is lower than the melting point of the pure metal, for example, the melting point of the chrome (Cr) is 1907 degrees Celsius.

In the current embodiment, the annealing process is conducted at the temperature 1850˜1905 degrees Celsius for 30˜120 seconds, and then the temperature is lowered and cooled with a rate of −7.5˜−20° C./sec to 950˜1000 degrees Celsius for 30˜120 seconds. Then the annealing oven stops heating till the temperature drops naturally to room temperature. The temperature of 1850˜1905° C. is maintained to ensure that when the metal post 50 of chrome reaches to its melting point, the chromic metal post 51 will naturally conduct a self-modification to create the metal ball 52. The reason for rapid decrease of the temperature is to prevent the formation of a Cr—Si alloy between chromic metal ball 52 and the mold insert 10 through an inter-diffusion process such that the volume and the true roundness of the metal ball will be negatively affected.

In addition, the removal of the photoresist pattern 30 will make the adjacent metal post 50 to have some deformation or breakage on its edge. In this case, the heating and annealing process (step S50) will transform the metal posts 50 into metal balls 52 with identical diameter as well as roundness. Accordingly, the deformation and breakage of the metal post 50 along its edge can be properly recovered by the heating and annealing process (step S50). On the other hand, the offset of the metal posts 50 resulted from the offset of the photoresist pattern 30 can also be corrected by the slightly displacement of the metal posts 50 during its liquidation and solidification.

Referring now to FIGS. 2 and 10, a process of dry etching (step S60) is disclosed. The dry etching process (step S60) is used to conduct a dry etching to the mold insert 10 so as to create a plurality of recesses 32 on the surface of the mold insert 10 which is not covered by metal balls 52. These recesses 32 can create a plurality of pattern which is the very pattern of the mold insert 10 to be used in the nono imprinting process.

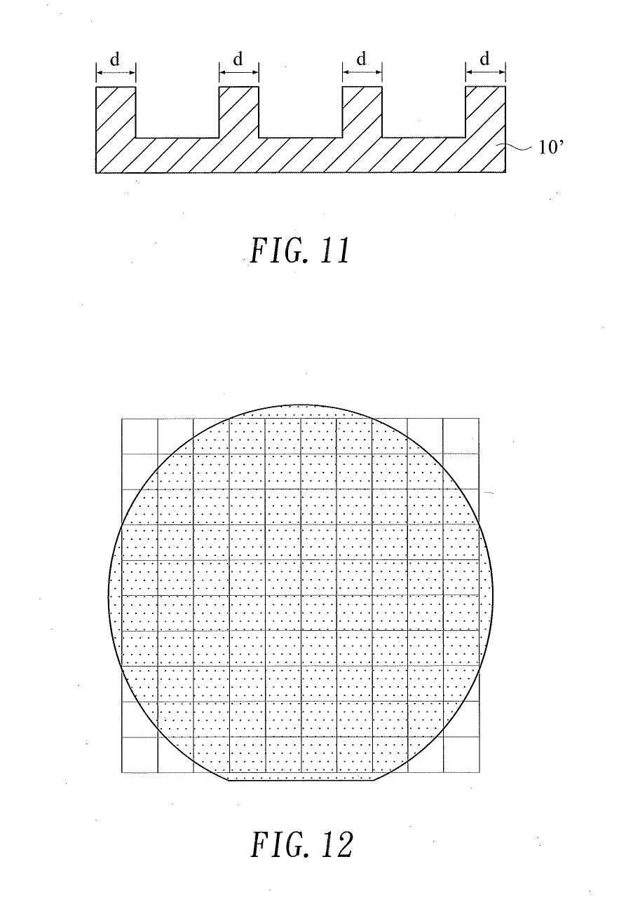

As shown in FIGS. 2 and 11, removal of the metal balls (step S70) is disclosed. This process is used to remove the metal balls 52 so as to create a defect free silicon mold insert 10′ with patterns having uniform distance “d” therebetween. Since the metal balls 52 have the identical diameter, and after the metal balls 52 are all removed from the mold insert 10′, the patterns of the defect free silicon mold insert 10′ will be featured with uniform distance “d” therebetween.

Referring to FIG. 12, the nano imprinting process can be incorporated with the mold insert 10′ made in accordance with the present invention to manufacture the epitaxial, wafer. Since the defect free silicon mold insert 10′ has featured function of correcting the deformation or offset. In light of this, when the mold insert 10′ is implemented into the nano imprinting process for the manufacturing of the epitaxial wafer free of any grid lines or scratches. The yield of the manufacturing of the epitaxial wafer can be effectively increased.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A method for fabricating defect-free silicon mold insert for nano imprint lithography, comprising the steps of:
providing a mold insert;
creating a photoresist pattern onto the mold insert, and further deploying a photoresist layer, exposing the photoresist layer with a mask and further performing developing process so as to create the photoresist pattern in which a plurality of holes are defined;
depositing a metal film covering the photoresist pattern and the plurality of holes;
creating a plurality of metal posts used to retrieve the metal film and the photoresist pattern, wherein the metal posts are created on the photoresist pattern in positions corresponding to the plurality of holes;
conducting a heating and annealing process melting the metal posts into a plurality of metal sections with heat and each of the metal sections being in a position corresponding to the original metal post, wherein every two adjacent metal sections are separated from each other, and annealing the metal sections into a plurality of metal balls;
conducting a dry etching process aiming to the mold insert having the metal balls so as to create a plurality of recesses on the mold insert through the gaps between the metal balls, defining a plurality of patterns by the recesses which is distant from each other with a yardstick of a radius of the metal ball; and
removing the metal balls from the mold insert so as to create a defect-free silicon mold insert having patterns with uniformed distance from each other.

2. The method for fabricating defect-free silicon mold insert for nano imprint lithography as recited in claim 1, wherein the mold insert is a hard substrate which is made from a monocrystalline silicon, polycrystalline silicon, silicon oxide, silicon carbide, aluminum nitride, alumina, spinel, zinc selenide, zinc oxide, gallium nitride, gallium phosphide, or a combination of more than two of the above-mentioned material.

3. The method for fabricating defect-free silicon mold insert for nano imprint lithography as recited in claim 1, wherein the metal film is made from a scandium, titanium, vanadium, chromium, manganese, iron, cobalt, nickel, copper, zinc, or a combination of more than any two of the metal described above.

4. The method for fabricating defect-free silicon mold insert for nano imprint lithography as recited in claim 1, wherein the metal balls have the same diameter.

5. The method for fabricating defect-free silicon mold insert for nano imprint lithography as recited in claim 1, wherein the metal balls have the same true roundness.

6. The method for fabricating defect-free silicon mold insert for nano imprint lithography as recited in claim 1, wherein the defect-free silicon mold insert is used in a nano imprint lithography for semiconductor manufacturing process.
